(19) United States
(12) Patent Application Publication
(10) Pub. No.: US 2004/0150103 A1
(43) Pub. Date: Aug. 5, 2004

(54) Sacrificial Metal Liner For Copper

(75) Inventors: Edward C. Cooney III, Jericho, VT (US); Robert M. Geffken, Burlington, VT (US); Jeffrey R. Marino, Fishkill, NY (US); Andrew H. Simon, Fishkill, NY (US); Anthony K. Stamper, Williston, VT (US)

Correspondence Address: IBM MICROELECTRONICS, INTELLECTUAL PROPERTY LAW, 1000 RIVER STREET, 972 E, ESSEX JUNCTION, VT, 05452, US

(73) Assignee: International Business Machines Corporation, Armonk, NY

(21) Appl. No.: 10/248,637

(22) Filed: Feb. 3, 2003

(51) Int. Cl. H01L 23/48

(52) U.S. Cl. 257/734

(57) ABSTRACT

A semiconductor device which includes an improved liner structure formed in a via having extended sidewall portions and a bottom penetrating a metal line. The liner structure includes two liner layers, the first being on the via sidewalls, but not the bottom, and the second being on the first layer and the extended sidewall portions and bottom of the via. A method of making the liner structure, in which the first layer is deposited prior to an etching or cleaning step, which extends the via into the metal line, is also disclosed.

### BACKGROUND OF INVENTION

1. Technical Field

The present invention relates generally to a semiconductor device and its method of manufacture. More particularly, the present invention relates to an improved liner structure, featuring a sacrificial component, especially for copper metallurgy.

2. Related Art

The interconnect structure of semiconductor devices comprises layers (wiring levels) containing conductive wires separated by interlevel dielectric layers (levels). The conductive wires are electrically isolated from one another by the dielectric layers. The conductive wires in each wiring level are interconnected by conductive vias extending from the conductive wires in one wiring level, through the interlevel dielectric layer, to the conductive wires in a second wiring level. In modern semiconductor devices, the conductive wires are partially embedded in or damascened into the dielectric layers.

As the speed of modern semiconductor devices has increased, interlevel-wiring capacitance has become a problem. Methods have been sought to reduce interlevel wiring capacitance. One solution that is becoming popular is the use of low-k dielectric materials such as SILK™ (a polyarylene ether, available from Dow Chemical, Midland, Mich.), spin on glass, polyimide or other polymers. These have replaced traditional dielectric materials such as silicon oxide and silicon nitride.

A problem with low-k dielectric materials is that they are not rigid like the traditional dielectric materials. Low-k materials are soft, compressible and flexible, have a low modulus and poor interfacial strength, i.e., they tend to delaminate or collapse under mechanical and thermal stress resulting in low yield, poor reliability and higher costs. Some low-k materials are brittle and tend to crack under mechanical or thermal stress. Their use in semiconductor devices presents two problems. First, because the conductive wires are comprised of metals (such as copper and tungsten), there is a mismatch in thermal expansion between low-k dielectrics and the metal which can lead to delamination, cracking or collapse of the low-k material during manufacture or in use in the field. Second, since the wires are formed by a damascene process, which includes a chemical-mechanical-polish (CMP) step, mechanical stress is induced into the device during CMP, which can lead to delamination, cracking or collapse.

Since low-k dielectric materials, damascene wiring levels, and CMP are basic to the fabrication of high performance semiconductor devices, a method for reducing or eliminating stress induced delamination, cracking or collapse of low-k dielectric layers is highly desirable.

Typically, a barrier or liner structure is deposited in the via, and a conductive material is deposited in the via on the liner structure. Prior to disposition of the liner structure, a cleaning of the via is usually performed, commonly by sputtering argon into the via. See, e.g., U.S. Pat. No. 6,177,347. Because the sputter etching is applied to sidewalls in the interlevel dielectric, this can lead to erosion of the dielectric material, which can redeposit on the via bottom at the interface with the underlying conductive wire, resulting in poor reliability.

Thus, there is a need in the industry for an improved liner structure, particularly for copper metallurical structures having low-k dielectrics, and an accompanying method of making such structures

### SUMMARY OF INVENTION

It is against this background, that the present invention introduces a sacrificial component into the liner structure and its fabrication, which is particularly advantageous for copper metallurgy with low-k dielectrics. In general, the improved liner structure includes a combination of liner layers, where the first liner layer is provided prior to via cleaning. In use, the first liner layer protects the via sidewalls (usually, low-k dielectric) from erosion during subsequent processing, such as sputter etching. During such processing, only first liner material will be removed, rather than dielectric, and this is not detrimental to interconnect reliability, robustness or resistance characteristics. Further, during sputter etching or cleaning, the first liner layer is removed from the via bottom, to avoid interconnect contamination during processing and to further enhance reliability. According to the invention, the via is also extended into the underlying metallization during etching; and a second liner layer is provided, which increases surface area in contact with the underlying metallization. The thicker liner structure on the via sidewalls adds mechanical strength, and better adhesion on the via bottom improves reliability, such as during subsequent thermal cycling. The liner structure also improves stress migration characteristics, which are particularly problematic in copper interconnects.

In accordance with the invention, there is provided a method of forming a liner structure in a via in the fabrication of a semiconductor device, comprising: providing a metal line over a semiconductor substrate; providing a dielectric layer over the metal line; forming in the dielectric layer a via having sidewalls and a bottom exposing the metal line; depositing a first liner layer in the via on the sidewalls and the bottom; anisotropically removing the first liner layer from the bottom, while leaving the first liner layer on the sidewalls and while extending the via so that extended portions of the sidewalls and the bottom penetrate the metal line; and depositing a second liner layer on the first liner layer left on the sidewalls and on the extended portions of the sidewalls and the bottom penetrating the metal line.

Further, in accordance with the invention, there is provided a method of forming a metallization structure in the fabrication of a semiconductor device, comprising: providing a metal line over a semiconductor substrate; providing a dielectric layer over the metal line; forming in the dielectric layer a via having sidewalls and a bottom exposing the metal line; depositing a first liner layer in the via on the sidewalls and the bottom; anisotropically removing the first liner layer from the bottom, while leaving the first liner layer on the sidewalls and while extending the via so that extended portions of the sidewalls and the bottom penetrate the metal line; depositing a second liner layer on the first liner layer left on the sidewalls and on the extended portions of the sidewalls and the bottom penetrating the metal line to form a liner structure in the via; and depositing a conductor over the liner structure to fill the via.

Additionally, in accordance with the invention, there is provided a semiconductor device comprising a liner structure, comprising: a metal line over a semiconductor substrate; a dielectric layer over the metal line; the dielectric layer including a via having sidewalls and a bottom, wherein extended portions of the sidewalls and the bottom penetrate the metal line; a first liner layer on the sidewalls but not on the bottom of the via; and a second liner layer on the first liner layer, the portions of the sidewalls penetrating the metal line and the bottom of the via.

The foregoing and other features and advantages of the invention will be apparent from the following more particular description of embodiments of the invention.

### BRIEF DESCRIPTION OF DRAWINGS

The embodiments of this invention will be described in detail, with reference to the following figures, wherein like designations denote like elements, and wherein:

FIGS. 1A-1E are schematic section views illustrating the method in accordance with the present invention; and

FIGS. 2A and 2B are cross-sectional SEM micrographs of metallization structures in accordance with the prior art and the present invention, respectively.

### DETAILED DESCRIPTION

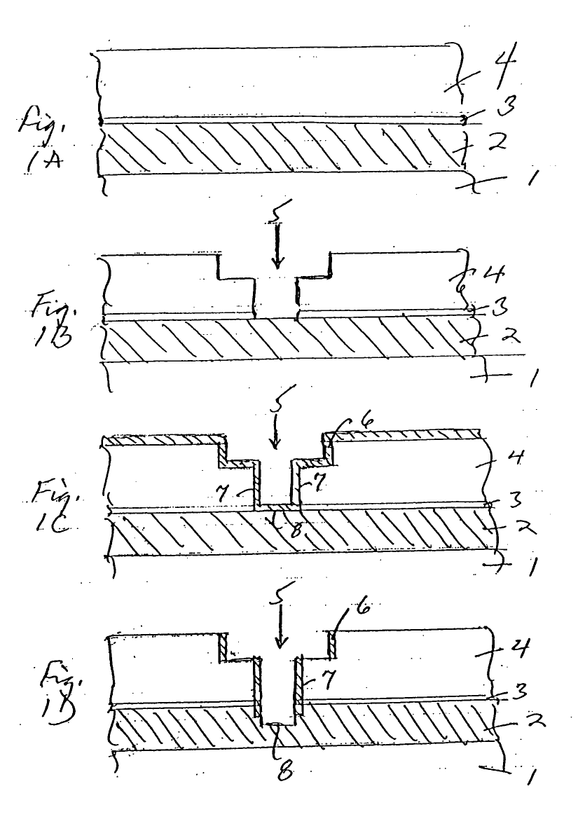

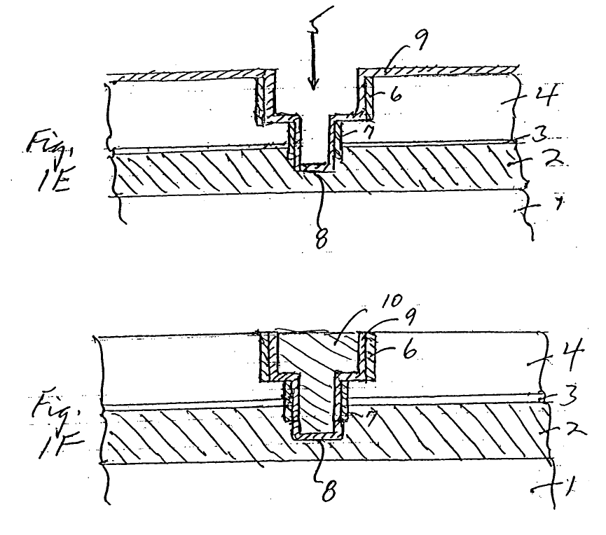

Referring to the drawings, FIG. 1A shows a semiconductor structure 1, which comprises a substrate, typically silicon, GaAs or the like, on which devices such as capacitors and transistors are formed and an insulator thereover. A metal line 2 is formed over the structure, followed by an insulator layer 3, which is typically silicon nitride or other suitable material. One or more additional layers of dielectric 4 are formed over the insulator layer 3 to provide a dielectric layer over the metal line 2.

Any suitable dielectric material or materials can be employed to form the dielectric layer 4, however, it is preferred that the layer 4 include a low-k dielectric, i.e. k<3.5, such as spin on glass, porous silicon oxide, polyimide, polyimide siloxane, polysilsesquioxane polymer, benzocyclobutene, parylene N, parylene F, polyolefin, polynaphthalene, amorphorus teflon, Black Diamond (available from Applied Materials, Santa Clara, Calif.), polymer foam or aerogel, and so forth. In a particularly preferred embodiment, the low-k dielectric is an oligomer, uncured polymer or cured polymer comprising the reaction product of one or more polyfunctional compounds containing two or more cyclopentadienone groups and at least one polyfunctional compound containing two or more aromatic acetylene groups wherein at least one of the polyfunctional compounds contain three or more groups selected from the group consisting of acetylene groups and cyclopentadienone groups. Advantageously, such a material has an ability to fill gaps and planarize patterned surfaces, while when cured has relatively high thermal stability and high glass transition temperature, as well as a low dielectric constant. Additional details concerning this particular material can be found in U.S. Pat. No. 5,965,679, the entire contents of which are incorporated herein by reference, as well as details concerning its preparation and use. Other low-k materials that can be employed will be known to those skilled in the art. Preferably, the metal line 2 comprises copper, although other metallurgies, such as aluminum, aluminum-copper, aluminum-copper-silicon, etc., may be used.

Referring to FIG. 1B, a dual damascene opening or via 5 is formed through the dielectric layer 4 and the silicon nitride layer 3, typically using a conventional two-mask process. For example, first a trough is formed to a depth less than the total thickness of the dielectric layer 4 by etching regions not covered by a first mask, which is then removed. Then, a narrower opening is etched in the bottom of the trough through to the underlying silicon nitride layer 3 using a second mask, which is also removed. Next, the silicon nitride layer 3 below the narrower opening is removed, typically using a CHF₃/O₂ dry etch. Although the via 5 illustrated in FIG. 1B is a dual damascene feature, it should be apparent that other features, such as a single damascene feature, could be formed in accordance with the invention.

Next, as shown in FIG. 1C, a conductive liner is formed in the via 5. First, a layer 6 comprising a refractory metal or a compound thereof is deposited, generally conformally, so as to coat the top surface of the dielectric layer 4 and the sidewalls 7 and bottom 8 of the via S. Preferably, the liner layer 6 is formed from tantalum, tantalum nitride, titanium, titanium nitride, a titanium-tungsten alloy or a combination thereof. Advantageously, the liner layer 6 is deposited prior to any via cleaning, such as by sputtering with argon. In this manner, the liner layer 6 protects the via sidewalls 7 from erosion, particularly when a low-k material is employed in the dielectric layer 4. By utilizing a metal film on the sidewalls 7, erosion protection is achieved, and any knock-off or re-sputter will removal metal material, which is not detrimental to interconnect reliability, robustness or resistance.

Referring to FIG. 1D, the liner layer 6 is removed from horizontal surfaces, i.e. from the top surface of the dielectric layer 4, any horizontal surfaces within the via, such as formed in a dual damascene feature and the bottom 8 of the via 5. However, it should be noted that suitable anisotropic etch conditions are selected so as to leave liner layer 6 on the via sidewalls 7. In a preferered embodiment, this can be attained by carrying out an argon sputter etch. Importantly, not only is liner layer 6 removed from the via bottom 5, but additionally there is significant erosion of the feature into meal line 2. Thus, portions of the via sidewalls 7 and bottom 8 penetrate the metal line 2; in so doing, this will serve to remove contaminants due to prior processing, and provide robust interconnect reliability.

By depositing liner layer 6, prior to any sputter etching or cleaning, the via sidewalls 7, and thereby dielectric layer 4, are protected from erosion. Performing a sputter cleaning step on the sidewalls 7, absent any conductive liner, would likely result in dielectric erosion with re-deposition on the via bottom 8, leading to poor reliability at the interface with metal line 2. Additionally, the sidewalls 7 are protected from re-deposition of metal (e.g. copper), which could subsequently migrate into the dielectric layer 4, causing reliability failure or other damage. On the other hand, by first depositing liner layer 6 on the sidewalls 7, any re-sputtered metal collects on the surface of the layer 6, not the dielectric layer 4.

Next, a second liner layer 9 is deposited, generally conformally, over the dielectric layer 4 and in the via 5, on the first liner layer 6 left on the via sidewalls 7 and on the extended portions of the sidewalls 7 and the bottom 8 penetrating the metal line 2, as shown in FIG. 1E. The second liner layer 9 preferably comprises a refractory metal or a compound thereof, more preferably, tantalum, tantalum nitride, titanium, titanium nitride, a titanium-tungsten alloy or a combination thereof.

Referring to FIG. 1F, after removal of the second liner layer 9 from the dielectric layer 4, such as by CMP, a conductive material 10 is deposited, as to fill the via 5, as well as coating the top surface of the dielectric layer 4. Then, another CMP process is performed to remove conductive material 10 from the top surface of the dielectric layer 4 and form a coplanar surface of conductive material 10, liner structure and dielectric layer 4. Any suitable conductive material 10 may be employed; however, tungsten, aluminum, aluminum-copper, aluminum-copper-silicon, and copper, are typical.

Preferably, the conductive material 10 comprises copper, where the copper content of the conductive material 10 is relatively high, generally at least 50%, and preferably above about 65%, so that the conductive material 10 has a relatively low resistivity. While substantially pure copper is generally preferred, small amounts of other materials may be included with the copper to, for example, improve resistance to corrosion. Other materials which may be employed in accordance with alternate embodiments of the present invention include, for example, gold, silver, nickel, and so forth.

Preferably, the conductive material 10 is deposited by electroplating, but other techniques, such as electroless plating can be employed, as will be apparent to those skilled in the art. In accordance with the embodiment of FIG. 1F, a plating base or seed layer is deposited over the second liner layer 9, using sputter deposition techniques, or other similar techniques, such as chemical vapor deposition, physical vapor deposition, etc. In this embodiment, the seed layer is copper, however, other materials may also be used, such as tungsten, titanium, tantalum, etc., depending on the form of plating technique used. Conductive material 10 is then deposited within the via 5 using an electrolytic plating technique. In particular, the structure which includes the via 5 is placed in a container of electroplate solution, an external current is applied, and the conductive material 10 grows onto the seed layer. Since the seed layer and the conductive material 10 are both copper in this example, as the conductive material 10 grows on to the seed layer the division between the seed layer and the conductive material 10 is eliminated. Once the via 5 has been filled with conductive material 10, the surface is planarized using chemical mechanical polishing or other suitable technique.

It should be noted that by forming the conductive liner structure in accordance with the invention, a thicker conductive liner results on the via sidewalls 7, providing enhanced mechanical strength, further improving reliability. In addition, by using a relatively heavy amount of sputtering, there is significant erosion of the feature into metal line 2, as noted hereinabove. Preferably, when the metal line 2 comprises copper, the extended portions of the via sidewalls 7 and the via bottom 8 penetrate the metal line 2 by a distance of at least about 200 Å, and preferably about 200-Å. This results in the conductive liner, as having a greater surface area in contact with the metal line 2, increasing adhesive strength of the interconnect, further improving reliability, such as from thermal cycling during processing.

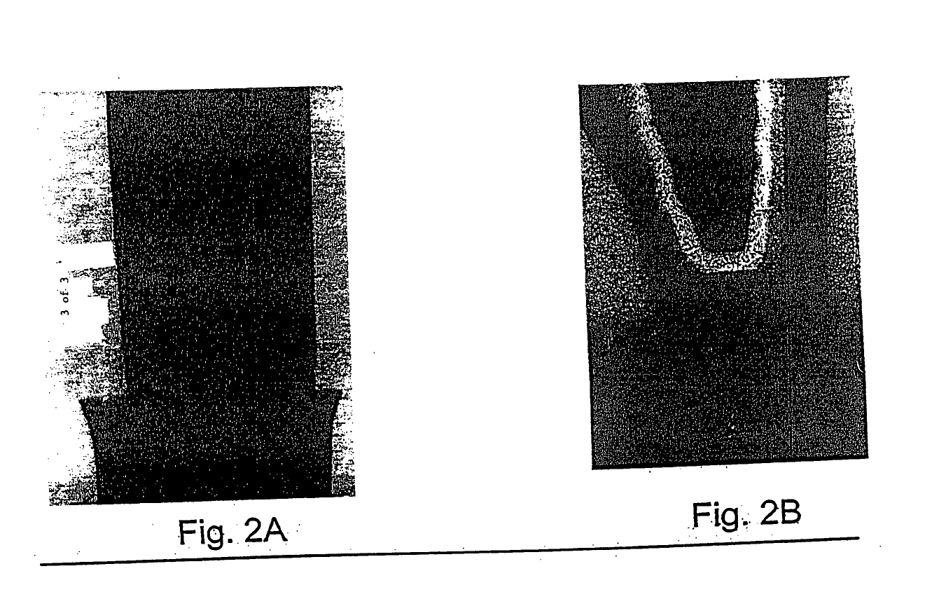

Without being bound by theory, it is also believed that improved stress migration results from significant sputter etch removal in the feature bottom, so as to provide a recessed feature in the metal line 2 having a stepped interface. Such improvement in stress migration is particularly significant as this is a typical failure mode in a conventional copper interconnect. For example, copper stress migration results from the movement of vacancies existing in the copper, and they typically diffuse along grain boundaries. However, these vacancies can diffuse much faster along a copper/silicon nitride interface, particularly if there is poor adhesion between the copper and silicon nitride. By having a stepped via sidewall/bottom penetrating the copper line, a blockage is created along the copper/silicon nitride interface, so that vacancies are blocked from moving past this location. See FIGS. 2A and 2B for a comparison of a metallization structure produced in accordance with the present invention (FIG. 2B) and a conventional structure (FIG. 2A).

While this invention has been described in conjunction with the specific embodiments outlined above, it is evident that many alternatives, modifications and variations will be apparent to those skilled in the art. For example, the present invention may be used in conjunction with semiconductor structures having various features, such as single damascene, and it is in no way intended to be limited to use with dual damascene features. It should also be understood that the conductive liner may comprise, in addition to the refractory metals or refractory metal compounds described above, other metals and metal compounds such as WN, MoN, WSiN, WSi, Nb, NbN, Cr, CrN, TaC, TaSiN, TiSiN, and so forth. Accordingly, the embodiments of the invention as set forth above are intended to be illustrative, not limiting. Various changes may be made without departing from the spirit and scope of the invention as defined in the following claims.

1. A semiconductor device comprising a liner structure, comprising:
a metal line over a semiconductor substrate;
a dielectric layer over said metal line;
said dielectric layer including a via having sidewalls and a bottom, wherein extended portions of the sidewalls and the bottom penetrate said metal line;
a first liner layer on the sidewalls but not on the bottom of the via; and
a second liner layer on said first liner layer, the portions of the sidewalls penetrating said metal line and the bottom of the via.

2. The semiconductor device of claim 1, wherein said dielectric layer comprises a low-k dielectric.

3. The semiconductor device of claim 2, wherein said low-k dielectric comprises an oligomer, uncured polymer or cured polymer comprising the reaction product of one or more polyfunctional compounds containing two or more cyclopentadienone groups and at least one polyfunctional compound containing two or more aromatic acetylene groups wherein at least one of the polyfunctional compounds contain three or more groups selected from the group consisting of acetylene groups and cyclopentadienone groups.

4. The semiconductor device of claim 1, wherein said metal line comprises copper.

5. The semiconductor device of claim 4, wherein the extended portions of the sidewalls and the bottom of the via penetrate said metal line by a distance of at least about 200 Å.

6. The semiconductor device of claim 1, wherein said liner layer comprises a refractory metal or a compound thereof.

7. The semiconductor device of claim 6, wherein said second liner layer comprises a refractory metal or a compound thereof.

8. The semiconductor device of claim 1, wherein said dielectric layer comprises a low-k dielectric; said metal line comprises copper; said first liner layer comprises a refractory metal or a compound thereof; said second liner layer comprises a refractory metal or a compound thereof; and the extended portions of the sidewalls and the bottom of the via penetrate said metal line by a distance ranging from about 200 Å to about 1000 Å.

9. The semiconductor device of claim 1, wherein the via is filled with a conductor.

10. The semiconductor device of claim 9, wherein the surface of said dielectric layer is coplanar with the conductor filling the via.

11. The semiconductor device of claim 10, wherein said conductor comprises copper.

12. The semiconductor device of claim 11, wherein said conductor comprises electroplated copper.

13. The semiconductor device of claim 12, wherein said metal line comprises copper; and the extended portions of the sidewalls and the bottom of the via penetrate said metal line by a distance of at least about 200 Å.

14. The semiconductor device of claim 13, wherein: said dielectric layer comprises a low-k dielectric; said first liner layer comprises a refractory metal or a compound thereof; said second liner layer comprises a refractory metal or a compound thereof; and the extended portions of the sidewalls and the bottom of the via penetrate said metal line by a distance ranging from about 200 Å to about 1000 Å.

15. The semiconductor device of claim 14, wherein the copper filled via is a dual damascene feature.
